(19) United States
(12) Patent Application Publication
(10) Pub. No.: US 2025/0385687 A1
(43) Pub. Date: Dec. 18, 2025

(54) READ-OUT CIRCUIT FOR READING OUT ELECTRICAL CURRENTS OF 10 NA AND/OR LESS AND USE OF A READ-OUT CIRCUIT AND METHOD FOR READING OUT THE READ-OUT CIRCUIT

(71) Applicant: HAHN-SCHICKARD-GESELLSCHAFT FÜR ANGEWANDTE FORSCHUNG E.V., Stuttgart (DE)

(72) Inventors: Markus KUDERER, Kirchzarten (DE); Mohammad AMAYREH, Freiburg (DE); Yiannos MANOLI, Freiburg (DE)

(73) Assignee: HAHN-SCHICKARD-GESELLSCHAFT FÜR ANGEWANDTE FORSCHUNG E.V., Stuttgart (DE)

(21) Appl. No.: 19/317,168

(22) Filed: Sep. 3, 2025

Related U.S. Application Data
(63) Continuation of application No. PCT/EP2024/055418, filed on Mar. 1, 2024.

(30) Foreign Application Priority Data
Mar. 3, 2023 (DE) 102023201963.9

(51) Int. Cl. H03M 3/00; H03F 1/26

(52) U.S. Cl. CPC H03M 3/422; H03F 1/26; H03M 3/368; H03F 2200/48

(57) ABSTRACT

A read-out circuit for reading out electrical currents of 10 nA or less is described, wherein the read-out circuit arrangement has a capacitive current amplifier and a continuous-time incremental sigma-delta modulator in the current mode. In addition, a use of the read-out circuit and a method for reading out the read-out circuit are described.

### CROSS-REFERENCE TO RELATED APPLICATIONS

This application is a continuation of copending International Application No. PCT/EP2024/055418, filed Mar. 1, 2024, which is incorporated herein by reference in its entirety, and additionally claims priority from German Application No. 10 2023 201 963.9, filed Mar. 3, 2023, which is also incorporated herein by reference in its entirety.

### TECHNICAL FIELD

The present invention relates to a read-out circuit for reading out electrical currents of 10 nA or less and a use of such a read-out circuit and a method for reading out such a read-out circuit.

### BACKGROUND OF THE INVENTION

Read-out circuits for reading out electrical currents are known from the conventional technology. For example, the publication by M. Bennati et al., “20.5 A Sub-pA ΔΣ Current Amplifier for Single-Molecule Nanosensors,” 2009 IEEE International Solid-State Circuits Conference—Digest of Technical Papers, 2009, pp. 348-349, 349a, doi: 10.1109/ISSCC.2009.4977451 describes a circuit concept which operates on a voltage-controlled ΔΣ converter (delta-sigma converter) with a background noise of less than 150 fAᵣₘₛ at 1 KHz and at room temperature. This circuit concept can be used for reading out nanosensors, nanopores. The circuit blocks of the converter in this publication comprise a charge integrator which is followed by a CDS circuit which contributes to the reduction of 1/f noise and offset and also functions as a sample-and-hold circuit (S/H). The abbreviation CSD stands for the English term “correlated double sampling”. The preamplifier integrates the input current for 120 μs and then carries out a reset for 8 μs. Therefore, the CDS block has a total sampling time of 128 μs, which limits the bandwidth to about 4 kHz. With a switch, the value of the feedback capacitor is set to operate with two different scale ranges ±200 pA and ±5 nA. After sampling the integrator output by the CDS block, the sampled value is subtracted at the end of the integration time. In sum, the input signal is thus integrated, then differentiated and sampled so that a voltage output is produced which is proportional to the input current. This publication discloses a separation between a so-called analog front-end device (AFE) and a voltage-to-digital converter. The AFE converts the current input into a voltage by correlated double sampling (CDS). The voltage is then converted into a digital output by a voltage-sigma-delta modulator.

WO 2010/122 293 A1 discloses a device for detecting an interaction of a molecular entity with a membrane protein in a lipid bilayer. The device comprises an arrangement of sensor elements which are arranged so that they output an electrical signal which depends on the occurrence of the interaction. In addition, the device comprises a detection circuit with detection channels which can amplify an electrical signal from a sensor element. More sensor elements than detection channels are provided, and detection channels are selectively connected to sensor elements which have an acceptable performance quality in that a lipid bilayer is formed and that an acceptable number of membranes are present.

When measuring very small currents in the pA range, as is often the case, for example, with nanopores and nanosensors, the current measurement becomes a challenge since the outputs consist of signals in the pA range or less, in the kHz range. In order to measure these values, very low-noise front-end amplifiers are generally necessary.

For example, the output noise of the integrator is usually sampled twice so that it doubles with correlated double sampling (CDS). A design of an SH circuit is usually required. The non-ideality of the SH circuit degrades the signal quality and therefore requires a careful design.

An object underlying the present invention is therefore to provide an improved read-out circuit for reading out electrical currents of 10 nA or less, in particular very small electrical currents in the range of a few pA. A further object is to provide a read-out circuit for reading out electrical currents of 10 nA or less, in particular very small electrical currents in the range of a few pA, which allow direct digitization of, in particular very small, electrical currents, i.e. of detected signals, without a substantial increase in the area or current consumption.

### SUMMARY

An embodiment may have a read-out circuit for reading out electrical currents of 10 nA and/or less, the read-out circuit arrangement including a capacitive current amplifier and a continuous-time incremental sigma-delta modulator in the current mode, wherein the continuous-time incremental sigma-delta modulator is configured to carry out a modulator reset upon receiving a second reset signal RST_{ICM}, wherein the read-out circuit is configured to carry out the modulator reset in time after carrying out the current amplifier reset, in particular to carry out the modulator reset in time after the current amplifier reset with a certain delay, wherein the certain delay is based on a settling time of an integrator of the at least one operational amplifier OP₁.

Another embodiment may have a use of an inventive read-out circuit in a nanopore read-out circuit or in a digital X-ray image sensor read-out circuit or in a gas sensor read-out circuit or in a read-out circuit for electrochemical sensors.

According to another embodiment, a method for reading out a read-out circuit which detects electrical currents of 10 nA and less, wherein the read-out circuit arrangement includes a capacitive current amplifier and a continuous-time incremental sigma-delta modulator in the current mode, may have the steps of: amplifying an input current Iᵢₙ which is in an order of magnitude of 10 nA or less in order to obtain an amplified current Iₒᵤₜ; and converting the amplified current Iₒᵤₜ into a digital value Dout, the method having the steps of: resetting the capacitive current amplifier upon receiving a first reset signal RST_{camp}, resetting the continuous-time incremental sigma-delta modulator upon receiving a second reset signal RST_{ICM}, wherein resetting the continuous-time incremental sigma-delta modulator is carried out in time after resetting the capacitive current amplifier.

According to the proposal, the read-out circuit for reading out electrical currents of 10 nA and/or less comprises a capacitive current amplifier and a continuous-time incremental sigma-delta modulator in the current mode. With the proposed read-out circuit, very small currents in the pA (piko amperes) range can be read out and further processed. In particular, these very small currents in the pA range can be digitized directly. The proposed read-out circuit can do without a CDS circuit. With the proposed read-out circuit, resetting the capacitive current amplifier and the continuous-time incremental sigma-delta modulator in the current mode can be carried out in temporal succession and separately from one another such that background noise is not digitized at all with the actual signal and is consequently not output as a digital signal either. This background noise is caused by resetting the capacitive current amplifier. Since resetting the capacitive current amplifier takes place temporally independently of resetting the continuous-time incremental sigma-delta modulator, the background noise, which is a charge noise which makes up a major part of the noise, is eliminated or is not converted into a digital signal at all. Other noise sources which are still digitized with the proposed circuit do not have a dominant noise component and are therefore rather negligible. The proposed read-out circuit can also be used for relatively large electrical currents in the nA range. However, the particular feature of the proposed read-out circuit is the use for detecting electrical currents in the pA range. One advantage of the proposed circuit is, for example, that by eliminating a noise source (the main noise source), relatively small currents can be measured and therefore the proposed circuit is suitable for detecting relatively small currents and very small currents. In the case of large currents, the proposed circuit allows a higher resolution or a larger background noise budget when using other components in the entire circuit.

A further aspect of the present invention relates to a use of a read-out circuit according to the invention in a nanopore read-out circuit or in a digital X-ray image sensor read-out circuit or in a gas sensor read-out circuit or in a read-out circuit for electrochemical sensors. The read-out circuit according to the invention can be used in many different sensor circuits in order to convert small or very small electrical currents detected by the sensors into a digital signal such that the converted digital signal can be used for further evaluation.

A further aspect of the present invention relates to a method for reading out a read-out circuit which detects electrical currents of 10 nA and/or less, wherein the read-out circuit arrangement comprises a capacitive current amplifier and a continuous-time incremental sigma-delta modulator in the current mode. The method firstly comprises amplifying an input current Iᵢₙ which is in an order of magnitude of 10 nA or less in order to obtain an amplified current Iₒᵤₜ. Subsequently, the method comprises converting the amplified current Iₒᵤₜ into a digital value Dₒᵤₜ. The digital value can then be used for further evaluation. The input current Iᵢₙ is based on a current detected by a sensor. The sensor is thus arranged upstream of a read-out circuit according to the invention, in other words the read-out circuit is coupled to a sensor which measures, i.e. detects, the input current. The input current is finally converted, by the read-out circuit, into the digital value which can be used for further evaluation.

The technical teaching described herein makes it possible to use the widely investigated continuous-time incremental sigma-delta analog-to-digital converter for measuring a current of 1 pA to 10 nA. In particular, no CDS (correlated double sampling) circuit is required here. The proposed read-out circuit and the corresponding method are thus simplified and at the same time improved since the read-out circuit as such is simplified. The technical teaching described herein offers an alternative to the widely used correlated double sampling circuit in charge integrators for measuring input current ranges of 1 pA to 10 nA.

Of course, individual aspects described with respect to the read-out circuit can also be implemented as a method step and vice versa. Further details will be discussed in the context of the following figure description.

### BRIEF DESCRIPTION OF THE DRAWINGS

Embodiments of the present invention will be explained in detail below referring to the appended drawings, in which:

FIG. 1 shows a read-out circuit according to the invention;

FIG. 2 shows a read-out circuit known from the conventional technology;

FIG. 3 shows the read-out circuit according to the invention of FIG. 1 with more details;

FIG. 4 shows a schematic representation of the mode of operation of the read-out circuit according to the invention;

FIG. 5 shows a schematic representation of the signals of a read-out of the read-out circuit according to the invention;

FIG. 6 shows a representation of a simulation result of the power spectral density (PSD) and a noise in the signal band (IBN; in-band noise) with respect to the frequency when using a continuous-time incremental second-order sigma-delta modulator;

FIG. 7 shows a schematic representation of a use of the read-out circuit according to the invention when detecting the electrical currents in a nanopore; and

FIG. 8 shows schematically the flow of the method according to the invention for reading out the read-out circuit according to the invention.

### DETAILED DESCRIPTION OF THE INVENTION

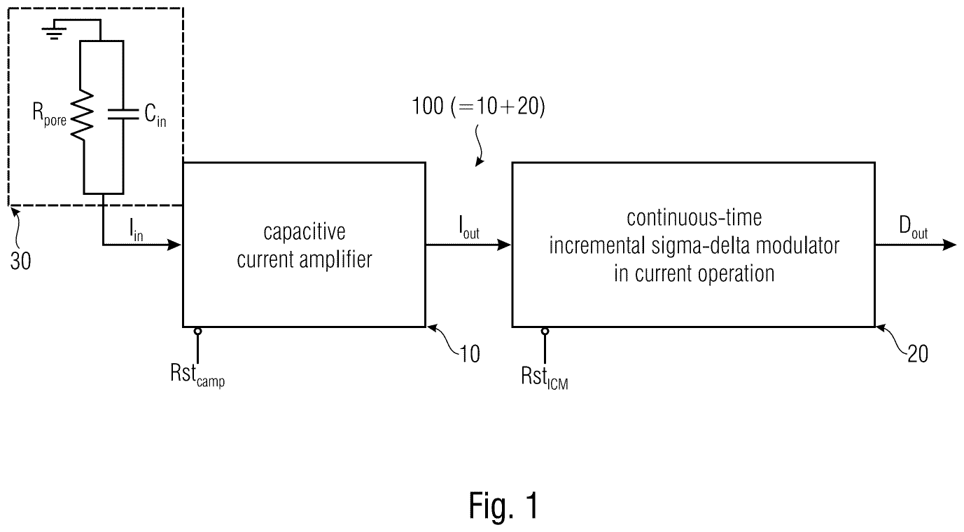

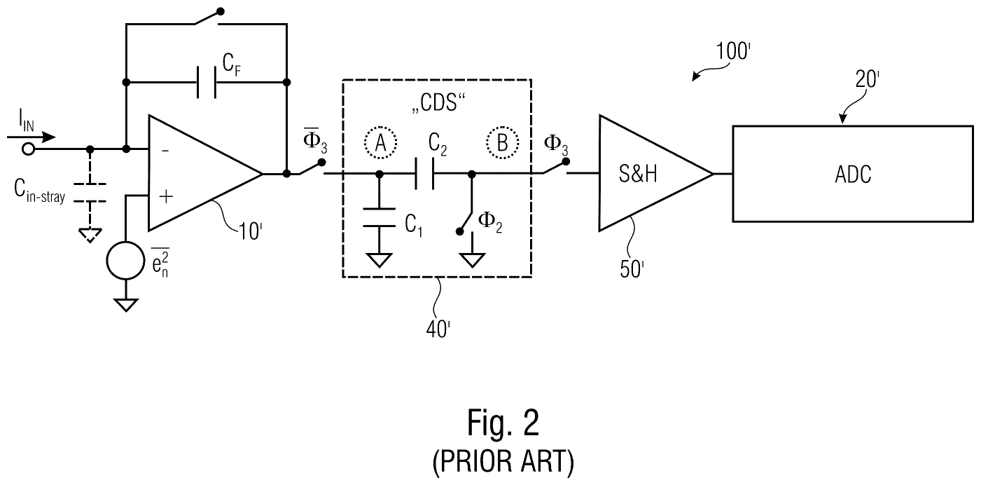

Individual aspects of the invention described herein will be described below in FIGS. 1 and 3 to 8. In the present application, identical reference signs relate to identical or identically acting elements, wherein not all the reference numerals in all the drawings, if they are repeated, have to be explained again. FIG. 2 shows a read-out circuit known from the conventional technology in order to allow a direct comparison with the read-out circuit according to the invention of FIG. 1.

FIG. 1 shows a read-out circuit 100 according to the invention. The read-out circuit 100 according to the invention for reading out electrical currents of 10 nA and/or less comprises a capacitive current amplifier 10 and a continuous-time incremental sigma-delta modulator 20 in the current mode. In the present case, current mode means current operation of the continuous-time incremental sigma-delta modulator 20. As indicated in FIG. 1, both the capacitive current amplifier 10 and the continuous-time incremental sigma-delta modulator 20 can be reset. Resetting the capacitive current amplifier 10 is indicated by the character Rst_{camp}, wherein camp stands for capacitive amplifier and rst stands for reset. Resetting the continuous-time incremental sigma-delta modulator 20 is indicated by the term Rst_{ICM}, wherein ICM is a known abbreviation for the incremental delta-sigma modulator. A read-out circuit 100 according to the invention for reading out electrical currents of 10 nA or less is suitable for reading out very small currents of only a few pA. In the present case, the term “very small currents” means electrical currents of a few pA (piko amperes). As can be seen in FIG. 1, the read-out circuit 100 is coupled to a sensor 30. In this case, the term “coupled” comprises being connected by means of cables. As shown in FIG. 1, the sensor 30 can be suitable for reading out nanopores, or the sensor 30 is provided by the nanopore. In other words, the nanopore is the sensor 30. The nanopore can be used for detecting certain molecules. The sensor 30 has, for example, a resistance Rₚₒᵣₑ in addition to an input capacitance Cᵢₙ. Furthermore, the nanopore can be modeled comprehensively as a pore resistance Rₚₒᵣₑ and a capacitance Cᵢₙ. The sensor 30 is not part of the read-out circuit 100, which is why the sensor 30 is represented by dashed lines. It can further be gathered from FIG. 1 that the capacitive current amplifier 10 of the read-out circuit 100 receives an input current Iᵢₙ, amplifies the input current Iᵢₙ and outputs it as an amplified current Iₒᵤₜ to the continuous-time incremental sigma-delta modulator 20. The continuous-time incremental sigma-delta modulator 20 thus receives the amplified current Iₒᵤₜ and converts the amplified current Iₒᵤₜ into a digital value Dₒᵤₜ which is used for further processing.

In the present case, the capacitive current amplifier represents a preamplifier 10 or an AFE (analog front-end) device. Furthermore, the continuous-time incremental sigma-delta modulator 20 represents an analog-to-digital converter.

FIG. 2 shows a read-out circuit 100′ known from the conventional technology which comprises an integrator 10′, a CDS (correlated double sampling) stage 40′, an SH (sample and hold) stage 50 and an analog-to-digital converter (ADC). According to the read-out circuit 100′ of FIG. 2 known from the conventional technology, the detected current Iᵢₙ is output as a digital value.

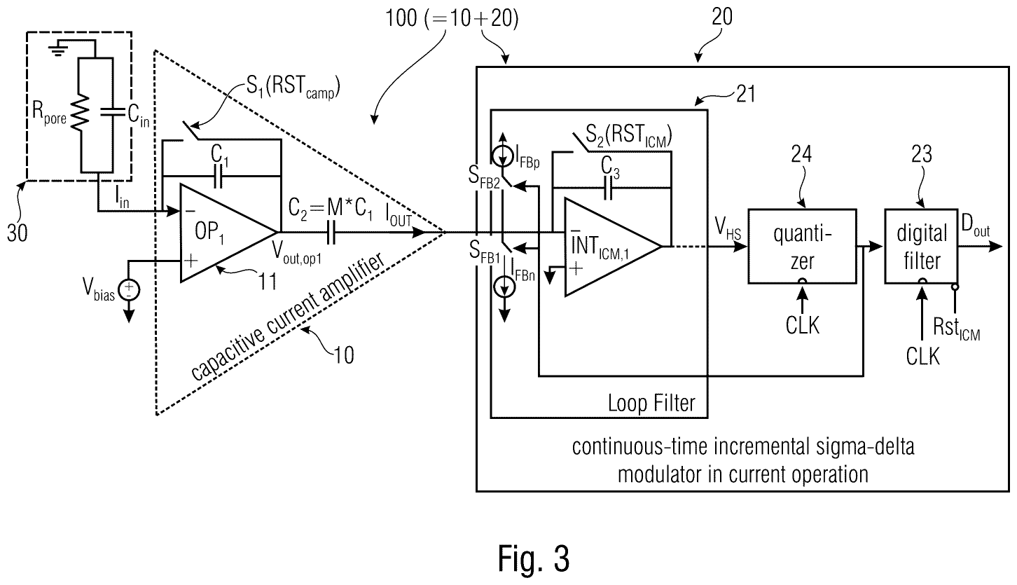

FIG. 3 shows the read-out circuit 100 according to the invention of FIG. 1 with more details. It can be seen from FIG. 3 that the capacitive amplifier 10 comprises a first capacitor C₁ in addition to an operational amplifier OP₁. A first switch S₁(Rstcₐₘₚ) is arranged in parallel connection with the first capacitor C₁ and the operational amplifier OP₁. In a closed state of the first switch S₁(Rstcₐₘₚ), the capacitive amplifier 10 is reset. In an open state of the first switch S₁(Rstcₐₘₚ), the detected electrical input currents Iᵢₙ are collected or integrated.

Preferably and as can be seen in FIG. 3, the current amplifier 10 is configured to amplify an input current Iᵢₙ in order to provide an amplified current Iₒᵤₜ at an output of the capacitive current amplifier 10, and wherein the continuous-time incremental sigma-delta modulator 20 is configured to receive the amplified current Iₒᵤₜ and convert it into a digital value Dₒᵤₜ. Description: The digital value Dₒᵤₜ is output at an output of the continuous-time incremental sigma-delta modulator 20 in order to further exploit or evaluate the digital value Dₒᵤₜ. Dₒᵤₜ corresponds to a digital current value which in turn corresponds to an averaged current value of a sampling interval.

The term “configured” is to be understood as “configured to do something”. The term “configured” here describes features which are not only suitable for carrying out the relevant steps/functions but rather have been specifically designed for this.

Preferably and as can be seen in FIG. 3, the capacitive current amplifier 10 is configured to carry out a current amplifier reset upon receiving a first reset signal RST_{camp}. In order to initialize resetting of the capacitive current amplifier, the first switch S₁(Rstcₐₘₚ) is closed. During the current amplifier reset, the first switch S₁(Rstcₐₘₚ) is therefore in the closed state. In the closed state of the first switch S₁(Rstcₐₘₚ), a feedback capacitance C₁ can be reset by discharging the feedback capacitance C₁.

Preferably and as can be seen in FIG. 3, the continuous-time incremental sigma-delta modulator 20 is configured to carry out a modulator reset upon receiving a second reset signal RSTICM. The continuous-time incremental sigma-delta modulator 20 comprises a second switch S₂(Rst_{ICM}). In order to initialize resetting the continuous-time incremental sigma-delta modulator 20, the second switch S₂(Rst_{ICM}) is closed. During the modulator reset, the second switch S₂(Rst_{ICM}) is in the closed state. In the closed state of the second switch S₂(Rst_{ICM}), the further capacitor C3 of the continuous-time incremental sigma-delta modulator 20 can be reset by discharging the further capacitor C3.

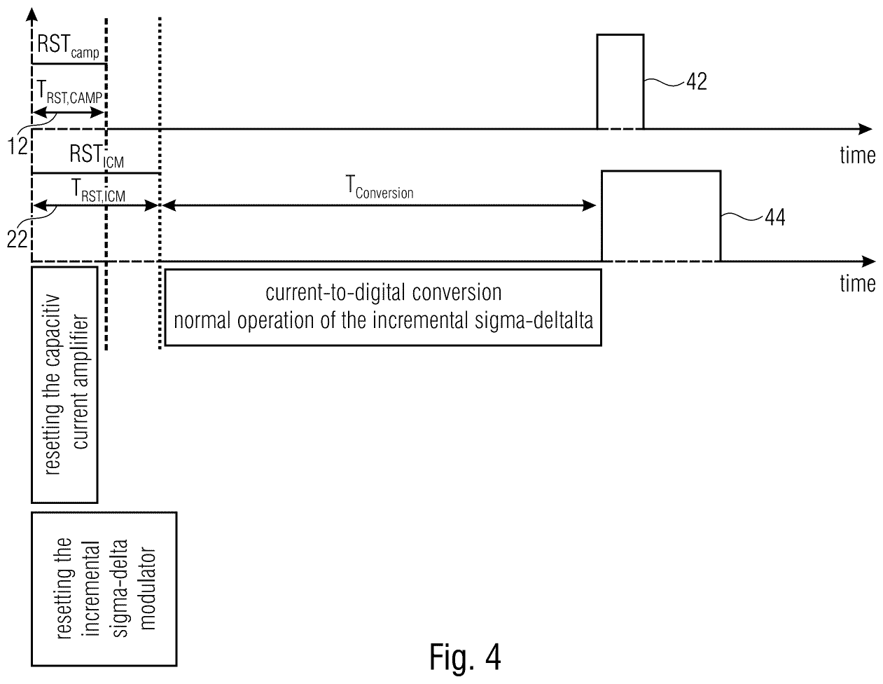

A first pulse duration 12 of the first reset signal RST camp and a second pulse duration 22 of the second reset signal RSTICM are superimposed in time such that the first and second pulse durations 12, 22 start/begin at the same time at the beginning of resetting the ICMs. This can be gathered, for example, from FIG. 4. Preferably, a first period duration of the capacitive amplifier 10 corresponds to a second period duration of the continuous-time incremental sigma-delta modulator 20. In other words, the period durations of the two reset signals RST_{camp} and RSTICM are the same. However, the first and second pulse durations 12, 22 of the two reset signals RST_{camp} and RSTICM are different. In FIG. 4, the pulse duration of the first reset signal RST camp is designated by T_{RST,CAMP} and the pulse duration of the second reset signal RSTICM is designated by T_{RST,ICM}. Both the reset signal RSTcamp and the reset signal RSTICM have a single period duration of T_{RST,ICM}+T_{conversion}, wherein T_{conversion} indicates a period duration which indicates a conversion time period (conversion period duration T_{conversion}) for digitizing the signal. In FIG. 4, the period duration T_{RST,ICM} appears to be twice as long as T_{RST,CAMP}, which can be, but does not necessarily have to be like this. FIG. 4 is not true to scale. For example, the pulse duration T_{RST,CAMP} of the capacitive amplifier 19 can be one microsecond and the pulse duration T_{RST,ICM} of the incremental sigma-delta modulator 20 can be two microseconds. The conversion time period T_{conversion} can be, for example, 8 microseconds. This would then result in a total of a period duration of 10 microseconds and thus a sampling rate of 100 KHz.

FIG. 4 shows a schematic representation of the mode of operation of the read-out circuit 100 according to the invention in the case of coupling with the sensor 30. Signal amplitudes over time are plotted in FIG. 4. The reset signals RST_{camp} and RST_{ICM} are digital signals. Their voltage levels are therefore either low or high. The low and high voltage values depend on the digital supply voltages used. In total, no units are required here since these are digital signals. High means true and Low means false, which is understood by a person skilled in the art and will therefore not be explained further.

Preferably, the current amplifier 10 comprises an output capacitance C₂ and at least one feedback capacitance C₁, wherein the amplified current Iₒᵤₜ is M times the input current Iᵢₙ, wherein M is a ratio between the output capacitance C₂ and the at least one feedback capacitance C₁. For example, the ratio is M=10 or M=9 or M=11.

Preferably, the current amplifier 10 comprises at least one operational amplifier OP₁, wherein the current amplifier 10 is configured to amplify the input current Iᵢₙ by the current amplifier 10 being configured to integrate the input current Iᵢₙ via the at least one feedback capacitance C₁ using the at least one operational amplifier OP₁. See FIG. 3. The first switch S₁(Rstcₐₘₚ) of the current amplifier 10 is then in an open state, i.e. the first switch S₁(Rstcₐₘₚ) is open during the integration of the at least one operational amplifier OP₁. An output voltage V_{out,op1} of the at least one operational amplifier OP₁ represents the integration of the input current Iᵢₙ. The output voltage V_{out,op1} of the at least one operational amplifier OP₁ is also formed via the capacitance value of the output capacitance C₂ which differentiates the voltage. Differentiating the voltage is to be understood as follows: The current which flows through a capacitance equals to C*dv/dt! Thus, C is the value of the capacitance and v is the voltage difference across the capacitance! Dv/dt means the derivation of the voltage across the capacitance as a function of time. This is why this is also called voltage differentiation. As a result, the output current Iₒᵤₜ will be M times the input current Iᵢₙ, wherein M is the ratio between C₂ and C₁.

Preferably, the read-out circuit 100 is couplable or is coupled to a sensor 30, wherein the capacitive current amplifier 10 is configured to regulate a voltage detected by the sensor 30 in the case of coupling, in particular to reset it to a command voltage V_{bias}. The sensor 30 is not necessarily part of the read-out circuit 100. Since the sensor 30 can be, for example, a nanopore or a gas sensor or another sensor, the sensor 30 is shown in FIG. 1 only by dashed lines. As can be gathered, for example, from FIG. 3, the sensor is connected to an input of the operational amplifier OP₁ of the amplifier 10 in the case of coupling with the read-out circuit 100. The connection can take place by means of cables or as a direct metal connection on a circuit board. The capacitive current amplifier 10 thus regulates the voltage across the sensor 30 and brings it back to the command voltage V_{bias}.

Preferably, the current amplifier 10 comprises a first switch S₁(Rstcₐₘₚ), which is arranged in parallel with the feedback capacitance C₁, wherein the capacitive current amplifier 10 is reset by closing the first switch S₁(Rstcₐₘₚ) using the first reset signal RST camp, which has a first pulse width T_{RST,CAMP}. This is represented schematically, for example, in FIG. 4. Here, the first pulse width T_{RST,CAMP} is represented over time. By closing the first switch S₁(Rstcₐₘₚ), the at least one operational amplifier OP₁ brings the voltage across the feedback capacitance C₁ and thus across the output capacitance C₂ back to the command voltage V_{bias}. When combining FIGS. 3 to 5, this can be gathered from the figures of the application.

Preferably, the continuous-time incremental sigma-delta modulator 20 comprises at least one loop filter 21, a quantizer 24 and a digital filter 23, as can be seen, for example, in FIG. 3. Here, the loop filter 21 comprises at least one second feedback capacitance C₃, at least one loop filter switch S₂(RST_{ICM}), a first feedback switch S_{FB1}, a second feedback switch S_{FB2} and at least one integrator INT_{ICM,1}, wherein the loop filter 21, in particular with the components just mentioned, is configured to receive and process the amplified current Iₒᵤₜ. The at least one loop filter switch S₂(RST_{ICM}) corresponds to the second switch S₂(RST_{ICM}) mentioned before. In the closed state, the at least one loop filter switch S₂(RST_{ICM}) serves to reset the continuous-time incremental sigma-delta modulator 20.

Preferably, the loop filter 21 has a loop filter output and the loop filter 21 is configured to provide an output voltage V_{HS} at the loop filter output, wherein the loop filter output is coupled to the quantizer 24 in order to sample the output voltage V_{HS} at each clock edge of a clock signal CLK. FIG. 3 shows the coupling between the quantizer 24 and the loop filter 21 or between the quantizer 24 and the digital filter 23.

Preferably, the quantizer 24 has a quantizer output and the quantizer 24 is configured to provide a feedback current I_{FBp}, I_{FBn} to the loop filter 21 in dependence on the output voltage V_{HS}, in particular to feed it back in order to regulate the output voltage V_{HS} in a specific range. Preferably, the specific range corresponds to a supply voltage range, i.e. a range in which the supply voltage of the read-out circuit 100 is located. The quantizer 24 is further configured to provide the amplified current Iₒᵤₜ at the quantizer output which corresponds to a digital bit stream.

Preferably, the digital filter 23 is coupled to the quantizer output and is configured to receive and filter the digital bit stream, wherein the digital filter 23 is configured to output a digital value Dout which is associated with the digital bit stream, after expiry of a conversion time period. This can be gathered from FIG. 3.

Preferably, the loop filter 21 comprises a switchable feedback current and one or more integrators, depending on the order of the continuous-time incremental sigma-delta modulator 20. In FIG. 3, for example, only one integrator INT_{ICM,1} is represented. The bit stream which is received by the quantizer 24 corresponds to the amplified current Iₒᵤₜ after passing through the loop filter 21. In other words, the amplified current Iₒᵤₜ at the output of the capacitive amplifier 10 is processed by the loop filter 21. The output voltage V_{HS} of the loop filter 21 is sampled by the quantizer 24 at each clock edge of the clock signal CLK. The output of the quantizer 24 activates one of the feedback currents I_{FBp} or I_{FBn} in dependence on the output voltage V_{HS}. As a result, the output voltage V_{HS} is regulated in a specific range and the output bit stream of the quantizer 24 represents the current Iₒᵤₜ. The bit stream is filtered by the digital filter 23 and a digital output value Dₒᵤₜ is generated at the end of the conversion time.

Preferably, resetting the continuous-time incremental sigma-delta modulator 20 is controllable by the second reset signal RST_{ICM}, which has a second pulse width T_{RST,ICM}, as can be seen in FIG. 4. Resetting the continuous-time incremental sigma-delta modulator 20 comprises resetting all integrators of the loop filter 21 and resetting the digital filter 23 and stopping the feedback currents I_{FBn,p} by opening the corresponding switches S_{FB2}, S_{FB1}. The switches S_{FB2}, S_{FB1} are used for proper operation of the continuous-time incremental sigma-delta modulator 20.

The capacitive current amplifier 10 is configured to separate the noisy virtual ground of the first integrator INT_{ICM,1} of the incremental sigma-delta 20 from the sensitive input current Iᵢₙ. The capacitive current amplifier 10 also reduces the noise requirements on the first integrator INT_{ICM,1} and the first feedback current I_{FB} of the continuous-time incremental sigma-delta modulator 20. In addition, the capacitive current amplifier 10 is configured to supply the bias voltage for the sensor 30.

Preferably, the first reset signal RST_{camp} of the current amplifier 10 and the second reset signal RST_{ICM} of the continuous-time incremental sigma-delta modulator 20 each have the same frequency, wherein the frequency defines a Nyquist sampling rate, in particular the first pulse duration 12 of the first reset signal RST_{camp} and the second pulse duration 22 of the second reset signal RST_{ICM} are superimposed in time such that the pulse durations 12, 22 start at the same time, as can be seen, for example, in FIG. 4 and has already been described in detail above, which reference is made to at this point. The term Nyquist sampling rate is a known term for a person skilled in the art, whose further explanation is not required.

Preferably, the readout circuit 100 is configured to carry out the modulator reset in time after carrying out the current amplifier reset, in particular to carry out the modulator reset in time after the current amplifier reset with a certain delay, wherein the certain delay is based on a settling time of an integrator 11 of the at least one operational amplifier OP₁. In FIG. 4, the certain delay is not shown due to the limited representation possibility. The certain delay is calculated on the basis of the settling time of the integrator 11 of the capacitive amplifier 10, wherein the certain delay is a function of the bandwidth BW_{INT} of the at least one integrator 11 of the capacitive amplifier 10. The certain delay time is proportional to

$$delay time = 5 / {BW}_{INT} ,$$

wherein BW_{INT} is the bandwidth of the integrator 11 of the capacitive amplifier 10, i.e. of the operational amplifier OP₁, in rad/s. The continuous-time incremental sigma-delta modulator 20 converts the amplified current Iₒᵤₜ into a bit stream, wherein this amplified current does not depend on the initial voltage value at the feedback capacitance C₁ or the output capacitance C₂.

Preferably, the read-out circuit 100 is configured, in the case of coupling with the sensor 30, to detect a charge noise at a sensor input capacitance Cᵢₙ of the sensor 30 when carrying out the current amplifier reset. In other words, the charge noise at the sensor input capacitance Cᵢₙ of the sensor 30 is detected during the current amplifier reset RST CAMP of the current amplifier integrator, i.e. while the switch S₁(RST_{CAMP}) is switched on, i.e. is closed. The switch S₁(RST_{CAMP}) can be modeled as a resistance Rₒₙ. When closing S₁(RST_{CAMP}), the operational amplifier OP₁ operates as a transimpedance amplifier with a feedback resistance of Ron of S₁(RST_{CAMP}). A virtual ground of the operational amplifier OP₁, i.e. the negative input, is noisy, and the noise depends on the noise of the resistance Rₒₙ of the switch S₁(RST_{CAMP}) and the voltage noise of the operational amplifier OP₁. When the switch S₁(RST_{CAMP}) is opened, the current noise amplitude at the negative input of the operational amplifier OP₁ is sampled at the capacitance Cᵢₙ (see FIG. 3). In the present case, the term sensor 30 means a device for detecting a physical parameter. A physical parameter means, for example, an electrical current, a magnetic field, a voltage or a mechanical or electrochemical force. After triggering the amplifier reset of the integrator 11 of the capacitive current amplifier 10, a charge noise at the input capacitance Cᵢₙ is detected or sampled. The charge noise is caused by the thermal noise of the switch-on resistance of the first switch S₁(RST_{camp}) and by the input-related voltage noise of the operational amplifier OP₁. This charge noise also depends on the entire input capacitance Cᵢₙ.

Preferably, the read-out circuit 100 is configured to first accumulate the charge noise on the input capacitance Cᵢₙ and subsequently integrate it via the feedback capacitance C1. The integration takes place after expiry of the settling time of the integrator 11 of the capacitive current amplifier 10. The settling time corresponds to the certain delay time and can therefore be calculated by delay time=5/BW_{INT}.

Preferably, the read-out circuit 100 is configured to integrate the charge noise via the feedback capacitance C1 during the modulator reset of the continuous-time incremental sigma-delta modulator 20. As a result, a digital value 42, which is obtained for the charge noise and is independent of the actual measured signal, can finally be obtained, as shown in FIG. 3. However, the digital value 42 of the charge noise is not contained in the digital value 44 of the actually measured signal. In other words: an amplified charge noise is also stored in the output capacitance C2, but since the continuous-time incremental sigma-delta modulator 20′ is at resetting during the integration of the charge noise, this charge noise will not enter into the digital bit stream and thus into the digital value Dₒᵤₜ at the output of the digital filter 23. This is because the charge noise was not integrated via the feedback capacitance C₃ of the first integrator INT_{ICM,1} of the continuous-time incremental sigma-delta modulator 20.

Preferably, an effect of the charge noise of the at least one integrator INT_{ICM,1} of the continuous-time incremental sigma-delta modulator 20′ on the digital value Dₒᵤₜ is reduced due to the upstream capacitive current amplifier 10, in particular to a negligible value. The charge noise which has accumulated on the total capacitance of the first integrator INT_{ICM,1} of the continuous-time incremental sigma-delta modulator 20 is involved in the digital final value Dₒᵤₜ, but its effect is reduced to a negligible value due to the current amplifier when it is referred back to the input.

Preferably, the read-out circuit 100 is configured to separate the at least one integrator IntICM,1 of the continuous-time incremental sigma-delta modulator 20 from the sensor input capacitance Cᵢₙ, wherein a bandwidth of the at least one integrator Int_{ICM,1} is capacitance-independent. A bandwidth of the read-out circuit can be 100 KHz. In other words: the capacitive current amplifier 10 separates the first integrator INT_{ICM,1} of the continuous-time incremental sigma-delta modulator 20 from the sensor capacitance Cᵢₙ, i.e. from the input capacitance Cᵢₙ of the sensor 30 in the case of coupling with the sensor 30. The sensor capacitance Cᵢₙ can be large or can change from one sensor to another. The sensor capacitance Cᵢₙ is large here if it comprises up to 10 pF. Thereby, the bandwidth of the first integrator of the sigma-delta INT_{ICM,1} is not affected by this changing capacitance, which is important for the stability of the modulator. A large input capacitance Cᵢₙ reduces the bandwidth of the integrator 11 and thus the bandwidth of the current amplifier 10. This leads to the fact that the integrator 11 needs more time for settling after the reset of the switch S1, which means that a larger pulse width of the reset signal RST camp is used. However, the stability remains unaffected by this.

Preferably, a corner frequency of the read-out circuit 100 corresponds to a reset frequency at which current amplifier resetting and modulator resetting take place. The total bandwidth of the read-out circuit 100 mainly depends on the signal transfer function of the digital filter 23, which depends on the structure of the continuous-time incremental sigma-delta modulator 20 used. In all cases, however, the corner frequency is at the reset frequency. This means that an analog anti-aliasing filter is not required in this case. However, this anti-aliasing filter could be implemented by the capacitive current amplifier by tuning the bias current or by tuning the compensation capacitance of the operational amplifier OP₁ in order to change its transfer function.

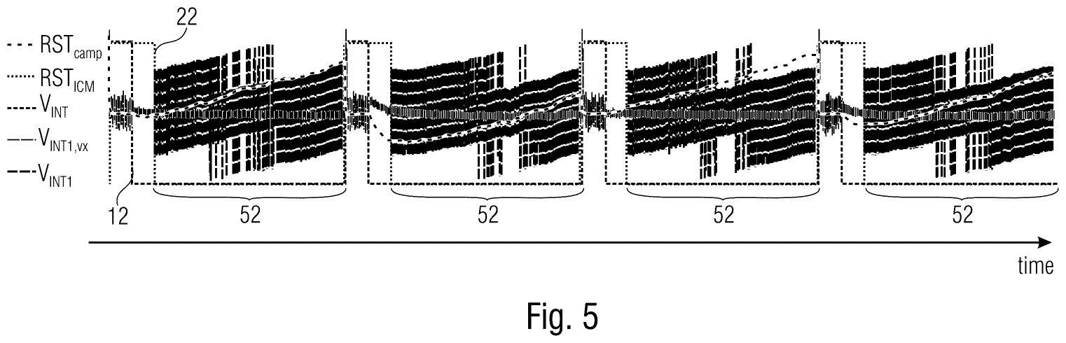

FIG. 5 shows a schematic representation of the signals of reading out the read-out circuit 100 according to the invention during operation of the read-out circuit 100. Voltage signals are represented in time flow during operation of the read-out circuit. The first feedback switch SFB₁ and the second feedback switch SFB₂ are open during resetting of the capacitive amplifier 10 and resetting of the continuous-time incremental sigma-delta modulator 20.

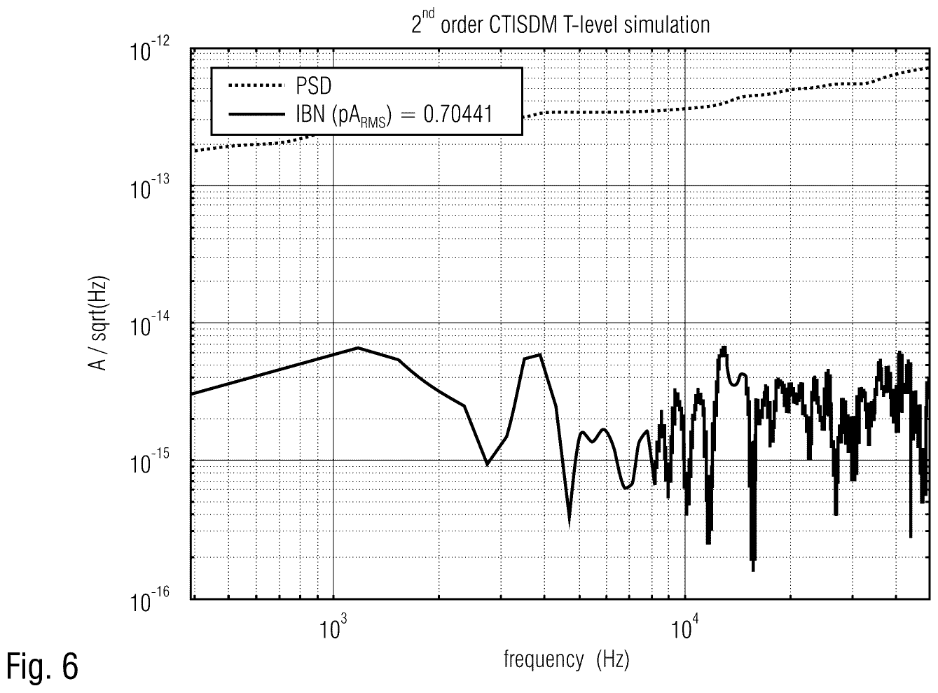

Upon receiving a reset signal RST_{camp}, first the switches S₁(RST_{camp}) and S₂(RST_{ICM}) are closed. FIG. 6 shows that noise in the signal band IBN (in-band noise) of almost 700 fA_{RMS} was achieved with an example implementation of the proposed read-out circuit 100 by an incremental second-order sigma-delta modulator 20, which operates at a clock frequency of 20 MHz and a reset frequency of 100 kHz, which corresponds to a total bandwidth of 50 kHz. The power spectral density PSD was calculated by first filtering the bit stream between two reset signals RST_{camp} and RST_{ICM} with a digital filter in the form of a cascade of digital integrators. In the present case, this means that the bit stream between two reset signals RST_{ICM} or between two reset signals RST camp was filtered with a digital filter in the form of a cascade of digital integrators. The power spectral density PSD is then calculated for the current values resulting from the digital filter and the noise over the bandwidth of 50 kHz was integrated.

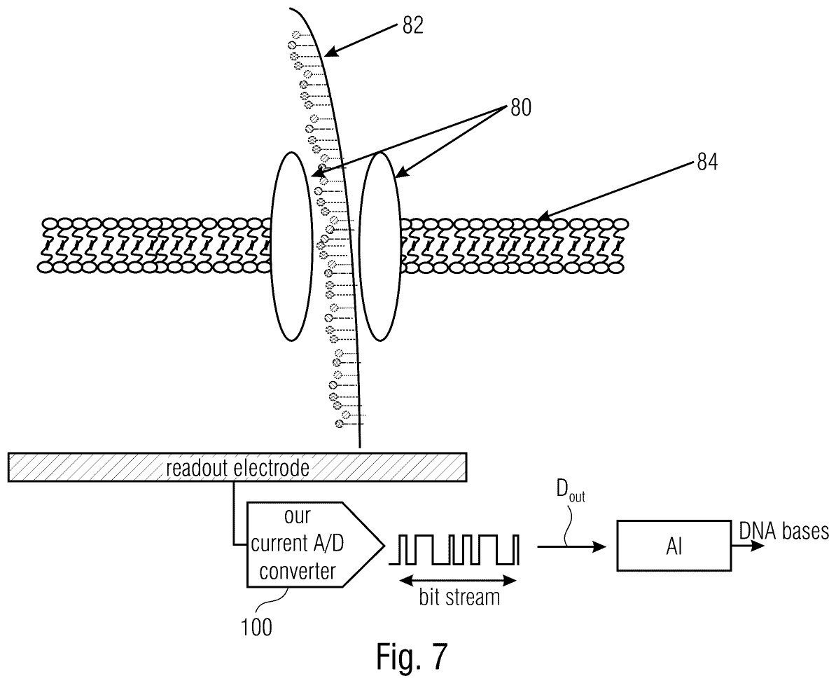

A further aspect of the present invention relates to a use of a read-out circuit 100, as has just been described, in a nanopore read-out circuit or in a digital X-ray image sensor read-out circuit or in a gas sensor read-out circuit or in a read-out circuit for electrochemical sensors. FIG. 7 shows, for example, a schematic representation of a use of the read-out circuit 100 according to the invention when detecting the electrical currents in a nanopore 80. As shown in FIG. 7, a DNA strand 82 of a DNA molecule is guided through a nanopore 80 (DNA for deoxyribonucleic acid), wherein an electrical current in the pA range is produced, which is detected using the read-out circuit 100 and finally digitized. The nanopore 80 as such is arranged in a double lipid membrane 84. The digital bit stream, which is finally output by the read-out circuit 100 in the form of the digital value Dₒᵤₜ, can be processed further or evaluated by artificial intelligence AI. Of course, other suitable devices can also be used for further evaluation, instead of AI.

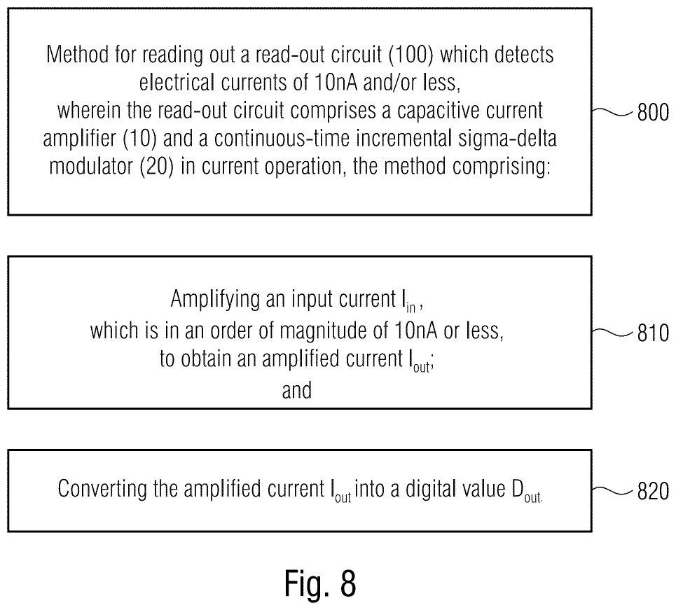

A further aspect of the present invention relates to a method for reading out a read-out circuit 100 which detects electrical currents of 10 nA and/or less. Such a method 800 is shown in FIG. 8. A read-out circuit 100 described herein is used for carrying out the method. Here, the read-out circuit 100 comprises a capacitive current amplifier 10 and a continuous-time incremental sigma-delta modulator 20 in the current mode. In step 810, the method comprises amplifying an input current Iᵢₙ which is in an order of magnitude of 10 nA or less in order to obtain an amplified current Iₒᵤₜ. This amplified input current Iᵢₙ is used to execute converting the amplified current Iₒᵤₜ into a digital value Dₒᵤₜ in step 820. This digital value Dₒᵤₜ can be processed further, as shown, for example, by AI, as FIG. 7 shows.

Preferably, the method 800 comprises resetting the capacitive current amplifier 10 upon receiving a first reset signal RST_{camp}, and resetting the continuous-time incremental sigma-delta modulator 20 upon receiving a second reset signal RST_{ICM}, wherein resetting the continuous-time incremental sigma-delta modulator 20 is carried out in time after resetting the capacitive current amplifier 10. The delay time already described above can be between resetting the capacitive current amplifier 10 and resetting the continuous-time incremental sigma-delta modulator 20. Reference is made here to what has been described above.

Preferably, the method 800 comprises sampling an output voltage V_{HS} at each clock edge of a clock signal CLK in order to regulate the output voltage V_{HS} in a specific range; and/or receiving and filtering the amplified current Iₒᵤₜ and converting the filtered, amplified current Iₒᵤₜ into the digital value Dₒᵤₜ after expiry of a conversion time period. Furthermore, the method 900 advantageously comprises regulating a detected voltage, in particular a command voltage V_{bias}, in the case of coupling with a sensor 30. Furthermore, the method 900 advantageously comprises, in the case of coupling with the sensor 30, sampling a charge noise at a sensor input capacitance Cᵢₙ of the sensor 30 when carrying out the current amplifier reset; and/or first accumulating the charge noise on an input capacitance Cᵢₙ of the sensor 30 and subsequently integrating the charge noise via a feedback capacitance C1 of the capacitive current amplifier 10; and/or integrating the charge noise via the feedback capacitance C1 during the modulator reset of the continuous-time incremental sigma-delta modulator 20.

A comparison of the present read-out circuit 100 with the known technology by M. Bennati et al., “20.5 A Sub-pA ΔΣ Current Amplifier for Single-Molecule Nanosensors,” 2009 IEEE International Solid-State Circuits Conference—Digest of Technical Papers, 2009, pp. 348-349, 349a, doi: 10.1109/ISSCC.2009.4977451 is summarized in the table (see below).

| | Bennati et al. | Read-out circuit according |
|---|---|---|
| | ISSCC 2009 | to the invention |
| Bandwidth (kHz) | 4 | 50 |
| Noise level (fA/sqrt(Hz)) | 5 | 3 |
| Power consumption (mW) | 23 | 20 |
| Input range (pA) | 200 | 200 |
| Chip area (mm²) | 0.5 | 0.5 |

A person skilled in the art understands that the device features described above can also be understood to be method steps. A detailed repetition of what has been described above is dispensed with in the context of the proposed method 900 in order to avoid redundancies. Advantages of the present technical teaching are as follows: the bit stream at the output of the quantizer 24 of the continuous-time incremental sigma-delta modulator 20 represents the segment of the input current signal between two resets (cf. with FIGS. 3 and 4). It contains more information when compared to a time-limited current sampling with correlated double sampling (CDS). In addition, the bit stream has a bandwidth which is equal to the clock frequency divided by two. This means that rapid current changes within the conversion time affect the bit stream. These rapid changes can represent, for example, characteristic molecular movements in DNA sequencing with nanopores which would otherwise not be detected by the correlated double sampling. For example, when used as a nanopore read-out circuit, an improvement in the sequencing accuracy is expected if the bit stream is used as an information source instead of discrete current samples as generated in correlated double sampling.

Further advantages are:
The separation of resetting the capacitive current amplifier 10 and the continuous-time incremental sigma-delta modulator 20 eliminates the KTC charge noise and other offset charges from the switch S₁(RST_{camp}) such as the charge injection and clock feed-through.
The amplification reduces the noise requirements on the current sources I_{FBn} and I_{FBp} and also the noise requirements on the first integrator of the continuous-time incremental sigma-delta modulator 20.
The capacitive amplifier 10 separates the sensor capacitance Cᵢₙ from the at least one integrator Int_{ICM1} of the continuous-time incremental sigma-delta modulator 20 so that the bandwidth (GBW) of the at least one integrator Int_{ICM1} is constant.
No additional filter is required to avoid aliasing effects (anti-aliasing). Filtering takes place by the digital filter 23, i.e. GBW of the at least one integrator Int_{ICM1} can be large in order to reduce the reset time of the capacitive amplifier 10 and thus reduce the information loss.
Direct current-to-digital conversion takes place.
Simple scaling by adapting the capacitances and the current sources I_{FBn} and I_{FBp} is possible.
Multiplexing is possible and the input channel can be switched on during resetting the continuous-time incremental sigma-delta modulator 20 in order to avoid errors.
Production costs, the used space on a chip area and the current consumption or current use are reduced.
The bit stream is richer in information! It is possible not to perform any filtering at all and to feed the bit stream directly into AI.
The quantization noise or also called Q noise can always be set lower than the thermal noise so that the resolution is maintained.

Although some aspects have been described in connection with a device or a system, it is to be understood that these aspects also represent a description of a corresponding method so that a block or a component of a device or a system is also to be understood to be a corresponding method step or as a feature of a method step. A representation of the present invention in the form of method steps is omitted in the present case for redundancy reasons.

In the preceding detailed description, various features have partly been grouped together in examples in order to rationalize the disclosure. This type of disclosure is not to be interpreted as intending that the claimed examples have more features than are expressly indicated in each claim. Rather, as the following claims reflect, the subject-matter may lie in less than all features of a single disclosed example. Consequently, the following claims are hereby incorporated into the detailed description, where each claim may stand as its own separate example. While each claim may stand as its own separate example, it is to be noted that, although dependent claims refer back in the claims to a specific combination with one or more other claims, other examples also comprise a combination of dependent claims with the subject-matter of each other dependent claim or a combination of each feature with other dependent or independent claims. Such combinations are included unless it is stated that a specific combination is not intended. Furthermore, it is intended that a combination of features of a claim with any other independent claim is also included, even if this claim is not directly dependent on the independent claim.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A read-out circuit for reading out electrical currents of 10 nA and/or less, the read-out circuit arrangement comprising a capacitive current amplifier and a continuous-time incremental sigma-delta modulator in the current mode, wherein the continuous-time incremental sigma-delta modulator is configured to carry out a modulator reset upon receiving a second reset signal RST_{ICM}, wherein the read-out circuit is configured to carry out the modulator reset in time after carrying out the current amplifier reset, in particular to carry out the modulator reset in time after the current amplifier reset with a certain delay, wherein the certain delay is based on a settling time of an integrator of the at least one operational amplifier OP₁.

2. The read-out circuit according to claim 1, wherein the current amplifier is configured to amplify an input current Iᵢₙ in order to provide an amplified current Iₒᵤₜ at an output of the capacitive current amplifier, and wherein the continuous-time incremental sigma-delta modulator is configured to receive the amplified current Iₒᵤₜ and convert it into a digital value Dₒᵤₜ.

3. The read-out circuit according to claim 1, wherein the capacitive current amplifier is configured to carry out the current amplifier reset upon receiving a first reset signal RST_{camp}.

4. The read-out circuit according to claim 1, wherein the current amplifier comprises an output capacitance C₂ and at least one feedback capacitance C₁, wherein the amplified current Iₒᵤₜ is M times the input current Iᵢₙ, wherein M is a ratio between the output capacitance C₂ and the at least one feedback capacitance C₁.

5. The read-out circuit according to claim 4, wherein the current amplifier comprises at least one operational amplifier OP₁, wherein the current amplifier is configured to amplify the input current Iᵢₙ by the current amplifier being configured to integrate the input current Iᵢₙ via the at least one feedback capacitance C₁ using the at least one operational amplifier OP₁.

6. The read-out circuit according to claim 1, wherein the read-out circuit is couplable or is coupled to a sensor, wherein the capacitive current amplifier is configured to regulate a voltage detected by the sensor in the case of coupling, in particular to reset it to a command voltage V_{bias}.

7. The read-out circuit according to claim 3, wherein the current amplifier comprises a switch S₁, which is arranged in parallel with the feedback capacitance C₁, wherein the capacitive current amplifier is reset by closing the switch S₁ using the first reset signal RST_{camp}, which comprises a first pulse width T_{RST,CAMP}.

8. The read-out circuit according to claim 1, wherein the continuous-time incremental sigma-delta modulator comprises at least one loop filter, a quantizer and a digital filter.

9. The read-out circuit according to claim 8, wherein the loop filter comprises at least one feedback capacitance C₃, at least one loop filter switch S₂, a first feedback switch SFB1, a second feedback switch SFB2 and at least one integrator INT_{ICM,1}, wherein the loop filter is configured to receive and process the amplified current Iₒᵤₜ.

10. The read-out circuit according to claim 8, wherein the loop filter comprises a loop filter output and the loop filter is configured to provide an output voltage V_{HS} at the loop filter output, wherein the loop filter output is coupled to the quantizer in order to sample the output voltage V_{HS} at each clock edge of a clock signal CLK.

11. The read-out circuit according to claim 8, wherein the quantizer comprises a quantizer output and the quantizer is configured to provide a feedback current to the loop filter in dependence on the output voltage V_{HS}, in particular to feed it back in order to regulate the output voltage V_{HS} in a specific range.

12. The read-out circuit according to claim 11, wherein the quantizer is configured to provide a digital bit stream which corresponds to the amplified current Iₒᵤₜ, at the quantizer output.

13. The read-out circuit according to claim 8, wherein the digital filter is coupled to the quantizer output and is configured to receive and filter the digital bit stream, wherein the digital filter is configured to output a digital value Dₒᵤₜ after expiry of a conversion time period.

14. The read-out circuit according to claim 1, wherein resetting the continuous-time incremental sigma-delta modulator is controllable by the second reset signal RST_{ICM}, which comprises a second pulse width T_{RST,ICM}.

15. The read-out circuit according to claim 3, wherein the first reset signal RST_{camp} of the current amplifier and the second reset signal RST_{ICM} of the continuous-time incremental sigma-delta modulator each have the same frequency, wherein the frequency defines a Nyquist sampling rate, in particular a first pulse duration of the first reset signal RST_{camp} and a second pulse duration of the second reset signal RST_{ICM} are superimposed in time such that the first and second pulse durations start at the same time.

16. The read-out circuit according to claim 1, wherein the read-out circuit is configured, in the case of coupling with the sensor, to sample a charge noise at a sensor input capacitance Cᵢₙ of the sensor when carrying out the current amplifier reset.

17. The read-out circuit according to claim 16, wherein the read-out circuit is configured to first accumulate the charge noise on the input capacitance Cᵢₙ and subsequently integrate it via the feedback capacitance C1.

18. The read-out circuit according to claim 17, wherein the read-out circuit is configured to integrate the charge noise via the feedback capacitance C1 during the modulator reset of the continuous-time incremental sigma-delta modulator.

19. The read-out circuit according to claim 2, wherein an effect of the charge noise of the integrator on the digital value Dₒᵤₜ is reduced due to the upstream current amplifier, in particular to a negligible value.

20. The read-out circuit according to claim 16, wherein the read-out circuit is configured to separate the at least one integrator IntICM,1 from the sensor input capacitance Cᵢₙ, wherein a bandwidth of the at least one integrator Int_{ICM,1} is capacitance-independent.

21. The read-out circuit according to claim 1, wherein a corner frequency of the read-out circuit corresponds to a reset frequency at which current amplifier resetting and modulator resetting take place.

22. A use of a read-out circuit according to claim 1 in a nanopore read-out circuit or in a digital X-ray image sensor read-out circuit or in a gas sensor read-out circuit or in a read-out circuit for electrochemical sensors.

23. A method for reading out a read-out circuit which detects electrical currents of 10 nA and less, wherein the read-out circuit arrangement comprises a capacitive current amplifier and a continuous-time incremental sigma-delta modulator in the current mode, the method comprising:
amplifying an input current Iᵢₙ which is in an order of magnitude of 10 nA or less in order to acquire an amplified current Iₒᵤₜ; and
converting the amplified current Iₒᵤₜ into a digital value Dₒᵤₜ,
the method comprising:
resetting the capacitive current amplifier upon receiving a first reset signal RST_{camp}, resetting the continuous-time incremental sigma-delta modulator upon receiving a second reset signal RST_{ICM}, wherein
resetting the continuous-time incremental sigma-delta modulator is carried out in time after resetting the capacitive current amplifier.

24. The method according to claim 23, comprising:
sampling an output voltage V_{HS} at each clock edge of a clock signal CLK in order to regulate the output voltage V_{HS} in a specific range; and/or
receiving and filtering the amplified current Iₒᵤₜ and converting the filtered, amplified current Iₒᵤₜ into the digital value Dₒᵤₜ after expiry of a conversion time period.

25. The method according to claim 23, comprising:
regulating a detected voltage, in particular to a command voltage V_{bias}, in the case of coupling with a sensor.

26. The method according to claim 25, comprising:
in the case of coupling with the sensor, sampling a charge noise at a sensor input capacitance Cᵢₙ of the sensor when carrying out the current amplifier reset; and/or
first accumulating the charge noise on an input capacitance Cᵢₙ of the sensor and subsequently integrating the charge noise via a feedback capacitance C1 of the current amplifier; and/or
integrating the charge noise via the feedback capacitance C1 during the modulator reset of the continuous-time incremental sigma-delta modulator.
